(19) United States
(12) Patent Application Publication
(10) Pub. No.: US 2012/0039690 A1
(43) Pub. Date: Feb. 16, 2012

(54) DEVICES AND METHODS FOR PROCESSING AND HANDLING PROCESS GOODS

(75) Inventors: Wolfgang STANGL, Eichenau (DE); Michael DOLCH, Eichenau (DE); Martin Maximilian MENSCHICK, Munich (DE)

(73) Assignee: SINGULUS STANGL SOLAR GMBH, Fuerstenfeldbruck (DE)

(21) Appl. No.: 13/055,156

(22) Filed: Jan. 21, 2011

Related U.S. Application Data
(63) Continuation of application No. PCT/EP2009/005288, filed on Jul. 21, 2009.

(30) Foreign Application Priority Data
Jul. 24, 2008 (DE) 102008034505.9

(51) Int. Cl. H01L 21/677

(52) U.S. Cl. 414/222.01; 414/806

(57) ABSTRACT

A device for processing a process good with a process medium has a provider for providing the process medium, and a transporter. The transporter has a transport element configured to move the process good along a process path between being accepted by a delivery device and being delivered to an accepting device and move with the process good from being accepted to being delivered. The process good enters the process medium laterally and is moved through same or is passed by same while floating on the process medium.

### CROSS-REFERENCE TO RELATED APPLICATIONS

This application is a continuation of copending International Application No. PCT/EP2009/005288, filed Jul. 21, 2009, which is incorporated herein by reference in its entirety, and additionally claims priority from German Application No. 102008034505.9, filed Jul. 24, 2008, which is also incorporated herein by reference in its entirety.

### BACKGROUND OF THE INVENTION

The present invention relates to devices and methods for processing and handling process goods and, in particular, to devices and methods suitable for handling plate-shaped process goods, such as, for example, semiconductor wafers, as are applied when manufacturing solar cells.

Semiconductor wafers and, exemplarily, poly-crystalline or mono-crystalline semiconductor wafers of small thicknesses in a range between 0.1 mm and 0.5 mm, such as, for example, 0.2 mm, are, when manufacturing solar cells, subjected to different process steps which, among others, include an etching process, a cleaning process and a drying process. In so-called batch systems, a number of wafers or substrates in a carrier are transported from one bath to the next by a gripper for performing such methods.

Methods for transporting semiconductor wafers through different wet regions are known, in which the wafers are placed on successive rolls such that a wafer will rest on at least two rolls. These rolls are each driven individually via main shafts and bevel gears, spur gears and endless means or the like. The rolls may comprise O-rings or cylinders as resting points for the wafers. These cylinders may be made of an absorbent material wetting the wafer with a medium. The wafers here are either transported horizontally or else the rolls form a path on which the wafers are lowered into the media regions and lifted again. Stop strips or washer disks are provided at the rolls in order to keep the wafers in their paths. With a horizontal transport, the medium flows over the wafers coming in and going out via a narrow slot, thereby ensuring a higher medium level. In order to prevent the wafers from floating, hold-down systems are employed. These in turn may again be rolls or cylinders which are driven separately or not. Such systems are principally employed by the Schmid Technology Systems GmbH and Rena GmbH companies, for example.

An alternative feeding system for wafers on endless means has already been employed by the applicant, in which a handling system puts a carrier provided with wafers on a feed chain which transports the basket through a basin. At the end of the basin, the basket is picked up again by a handling system.

There is demand for devices and methods for processing process goods which allow process goods to be handled so as to treat the materials with care.

### SUMMARY

According to an embodiment, a device for processing a process good with a process medium may have: means for providing the process medium; and transport means having a transport element configured to move the process good along a process path between being accepted by a delivery device and being delivered to an accepting device so as to move with the process good from being accepted to being delivered, wherein the device is configured such that the process good enters the process medium laterally and is moved through same or passed by same while floating on the process medium, wherein the means for providing the process medium has: a process medium reservoir covered by a plate, the plate having a top surface, and the plate being perforated by a plurality of openings, and means for filling the process medium reservoir such that the process medium reservoir overflows and thereby the process medium is driven through the openings onto the top surface.

According to another embodiment, a system for processing a process good with a process medium may have: a processing device having a device for processing a process good with a process medium as mentioned above; and at least either a delivery device configured to feed the process good for being accepted by the processing device; or an accepting device configured to accept the process good from the processing device.

According to another embodiment, a method for processing a process good with a process medium may have the steps of: accepting the process good by a processing device from a delivery device; providing the process medium by means of a process medium reservoir covered by a plate, the plate having a top surface, and the plate being perforated by a plurality of openings, wherein the process medium reservoir is filled such that it overflows and thereby the process medium is driven through the openings onto the top surface; by a transport element of a driving device of the processing device, which moves along the process path with the process good from accepting the process good to delivering the process good, moving the process good along the process path, the process good entering the process medium laterally and being moved through same or being passed by same while floating on the process medium; and delivering the process good to an accepting device after having passed the process path.

According to still another embodiment, a device for handling a process good may have: a delivery device having first endless means which has a transport element for transporting the process good to a delivery region in which the endless means travels around an axis at a first radius; an accepting device having second endless means for accepting the process good in the delivery region and for transporting the process good from the delivery region, the second endless means traveling around the same axis at a second radius such that the second endless means moves faster than the first endless means, wherein the ratio between the first and second radii is such that the second endless means moves the process good from a track of travel of the transport element around the axis at such a speed that the process good does not interfere in the movement of the transport element around the axis.

Embodiments of the invention are based on the finding that it is possible to expose a process good to a process medium and, in particular, a process liquid in a particularly careful manner by the process good entering the process medium laterally and being moved through same or passed by same while floating on the process medium. This allows reducing strain in particular in a plate-shaped process good of small thickness, such as, for example, poly-crystalline or mono-crystalline semiconductor wafers having a thickness between 0.1 mm and 0.5 mm, when processing same with a process medium and, in particular, a process liquid. This allows reducing breaking of the process good and, consequently, rejects. Embodiments of the invention may particularly be adapted for processing and handling poly-crystalline or mono-crystalline silicon wafers of a thickness in the range of 0.2 mm.

Embodiments of the present invention relate to devices and methods for processing and handling solar cell wafers which may be semiconductor wafers of the type described above.

In embodiments of the present invention, the process medium is a process liquid and, in particular, an etching liquid or a cleaning liquid. In alternative embodiments of the invention, the process medium may be a liquid containing components which cause the process good to be coated when contacting the process good by the process medium, due to a chemical reaction.

Embodiments of the invention relate to devices and methods in which the process good, such as, for example, a wafer or a substrate, is transported separately and individually. In embodiments, the invention relates to devices and methods in which the transport means is configured to transport wafers or substrates through a system separately one after the other in one or several rows.

Due to the fact that, in embodiments of the invention, the process good enters the process medium laterally, the movement of the process good, caused by the transport element, along the process path through the processing device may be a movement purely horizontal relative to the earth's gravitational field. This allows material to be transported in a careful manner.

In order to implement the process good entering the process medium laterally, embodiments of the invention include a process medium reservoir filled with a process medium such that a process medium projection or supernatant or liquid projection or supernatant forms above an upper boundary of the process medium reservoir above which the process good is fed. Lateral walls may be provided so as to support the formation of such a liquid projection. In alternative embodiments, the process good may enter the process medium laterally via lateral openings in a process medium reservoir. Alternatively, the means for providing the process medium may comprise an opening plate and/or a plurality of nozzles for feeding the process medium from above the process path such that the process good enters the process medium provided by the opening plate or the plurality of nozzles laterally.

### BRIEF DESCRIPTION OF THE DRAWINGS

Embodiments of the present invention will be detailed subsequently referring to the appended drawings. Same elements or elements of the same effect are, where applicable, provided with the same reference numerals in the drawings, in which:

FIGS. 1a and 1b show embodiments of a processing device including a hold-down function schematically;

FIG. 2 shows an embodiment of a processing device including rest regions for a process good schematically;

FIGS. 3a and 3b show alternative embodiments of a processing device schematically;

FIGS. 4a, 4b, 5, 6a, 6b, and 7 show variations of embodiments of processing devices schematically;

FIGS. 8a to 8d show a perspective view, a side view, a top view and a front view, respectively, of an embodiment of a processing device schematically;

FIGS. 9a to 9e show representations for illustrating operation of a device for handling a process good schematically;

FIGS. 10a to 10d show a perspective view, a side view, a top view and a front view, respectively, of an embodiment of a processing device;

FIGS. 11a to 11c show schematic illustrations of an alternative embodiment of a processing device; and

FIGS. 12a and 12b show a schematic isometric illustration and a schematic side view of an embodiment of an accepting/delivery device.

### DETAILED DESCRIPTION OF THE INVENTION

The present invention will subsequently be described in particular using devices and methods for processing process goods in the form of poly-crystalline or mono-crystalline semiconductor wafers. However, it is obvious that embodiments of the invention may also be configured for processing or handling different process goods, such as, for example, glass panels or other plate-shaped process goods.

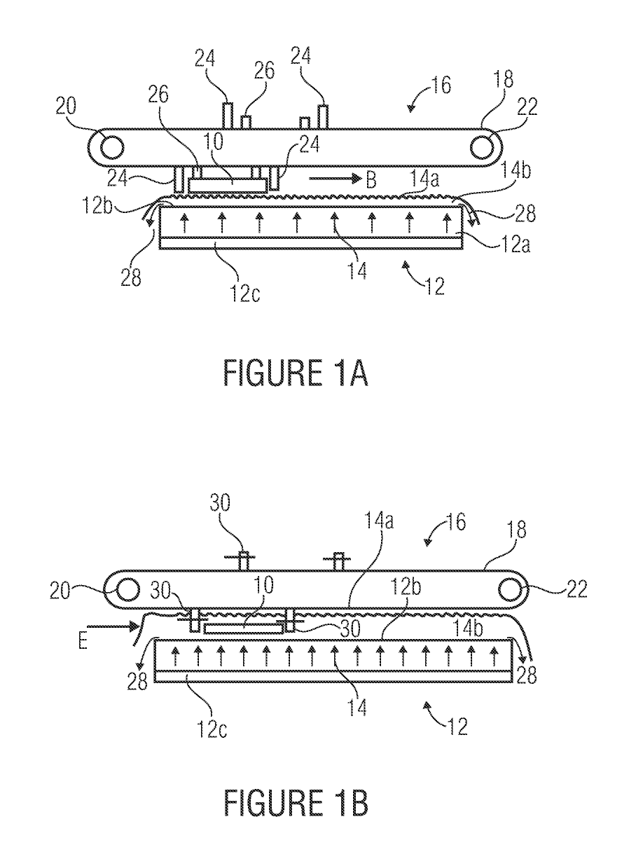

FIG. 1a shows a processing device for a process good 10 which may exemplarily be a semiconductor wafer of an essentially square shape having a thickness of 0.2 mm and an edge length of usually up to 156 mm, as is applied when manufacturing solar cells, which, however, is by no means limiting, schematically.

The processing device includes means 12a for providing a process medium and, in particular, a process liquid which a process medium reservoir 12a comprises. Filling means 12c for filling the process medium reservoir with the process medium is also provided. The filling means 12c is configured to cause overflow of the process medium reservoir 12a such that a process medium projection 14 is produced above an upper boundary 12b of the process medium reservoir 12a.

It is to be mentioned here that, in embodiments of the invention, the upper boundary 12b of the process medium reservoir may exemplarily be formed by a hole plate comprising a plurality of holes through which the process medium reaches the top surface thereof so as to form a process medium film there. Lateral boundaries may be provided so as to prevent lateral overflow of the process medium such that same only flows over the front and back edges of the process medium reservoir 12a.

Transporting means is provided for moving the process good 10 in a direction B along a process path. The transport means 16 includes endless means 18 which may be rotated about two axes 20 and 22 or about rolls or discs resting on the axes. Transport elements 24, some of which are schematically shown in FIG. 1a and provided with the reference numeral 24, are attached to the endless means. Additionally, hold-down elements 26 are attached to the endless means. A motor (not shown) for driving the endless device 18 so as to move, as is shown in the Figures, in a counter-clockwise direction is provided.

In operation, the medium reservoir 12a is supplied with the process medium, as is indicated in the Figures by respective arrows, using the filling means 12c which may exemplarily be implemented by a pump and corresponding fluid interconnects such that the process medium projection 14 above the upper boundary 12b of the process medium reservoir 12a is produced. The process medium or process liquid here may flow over at the, in the direction of movement B, front and back ends of the medium reservoir 12a as is indicated in the Figures by respective arrows 28. Lateral boundaries may be provided so as to prevent lateral overflow.

The motor (not shown) drives the transport means 16 such that the endless means 18 rotates in a counter-clockwise direction. The transport elements 24 here are rotated about the axis 20 and accept the process good 10 from a delivery device (not shown in FIG. 1a) at the left-hand end of the transport means, by a transport element 24 engaging the back end of the process good 10. With an ongoing movement in the direction of movement B, the transport element 24 acts as a pusher element for the process good 10 and moves through the processing device along the process path together with the process good. In the region of the axis 22, the transport element 24 finally loses contact with the process good 10 when moving around the axis 22 to the top together with the endless means 18.

As can be seen in FIG. 1a, the transport means 16 and the means for providing the process medium 12 are arranged such that the process good 10 is passed by same while floating on the process medium 14. The process good is positioned by the hold-down elements 26 which may be implemented as pins. A flow caused by the filling of the process medium reservoir 12a from the bottom to the top here may have a buoyant effect on the process good.

In the embodiment shown in FIG. 1a, it is possible to process only the bottom side of the process good 10 with the process medium.

In the example shown in FIG. 1a, the process good is thus transported on the process medium level. Alternatively, it is possible to transport the process good below the process medium level by arranging the transport means 18 and the means for providing the process medium such that the hold-down elements hold the process good immersed into the process medium. An embodiment where such a procedure is implemented is shown in FIG. 1b.

The means 12 for providing a process medium 14, shown in FIG. 1b, may basically correspond to the means shown in FIG. 1a. Additionally, the transport means 16 may also correspond to the transport means shown in FIG. 1a, wherein only the transport means 16 is arranged relative to the means 12 such that the process good 10 is held below the medium level of a medium projection formed by the upper boundary 12b, by transport elements 30. In the embodiment shown in FIG. 1b, the transport elements are made to be T-shaped such that they are effective as both hold-down elements and pusher elements.

The mode of functioning of the processing device shown in FIG. 1b basically corresponds to the mode of functioning described above making reference to FIG. 1a, with the exception that the transport means 16 causes the process good 10 to enter the process medium 14 laterally at the position of the arrow E.

It is to be explained here that the transport means 16 are configured such that the movement of the process good 10, caused by the transport elements 24 and 30, along the process path is a movement purely horizontal relative to the earth's gravitational field, wherein the process medium may cause slight floating up and down of the process good, but only in a very limited range of exemplarily less than 5 mm or less than 1 mm.

In FIGS. 1a and 1b, only exemplarily, some transport elements and hold-down elements 24, 26 and transport elements 30 are illustrated. It is to be pointed out here that the endless means 18 may comprise corresponding elements in a distributed manner along the entire length thereof so that process good 10, such as, for example, in the form of semiconductor wafers or semiconductor substrates, may be moved along the process path separately one after the other. Thus, a transport element 24 or 30 may be effective as both a pusher for an upstream process good and as a stopper for a downstream process good.

Additionally, it is pointed out that the embodiment shown in FIG. 1a may comprise T-shaped transport elements and the embodiment shown in FIG. 1b may comprise transport elements and hold-down elements as are shown in FIG. 1a.

In embodiments of the invention, the process good may be transported while floating on a process medium pad. Thus, the process good may exemplarily be accepted by delivering means or be delivered to an accepting means in which the process good also floats or rests on a medium pad or a gas pad. In a system comprising several sections, the process good may, depending on the section, float on a medium film which exemplarily flows in from below via distributor plates, or glide on a gas pad, such as, for example, air, N₂, etc. The transport means may, as is described, comprise endless means, such as, for example, a chain, a belt and the like, where corresponding transport elements, such as pushers and hold-down elements, are attached. Alternatively, a carriage may be provided to which corresponding hold-down elements and pushers are attached and which moves the process good along the process path. In embodiments, the endless means may comprise two endless means spaced apart from each other in a direction transverse to the transport direction, where respective transport elements are attached. In addition, lateral guides may be attached to the transport means so that movement of the process good perpendicular to the direction of movement B can be limited. Thus, the process good can be guided in the horizontal plane and be limited in the Z axis (hold-down function).

Embodiments in which the process good floats on a medium film allow little mechanical strain on the process good, single-side treatment of the surfaces, good medium exchange on the process good surface, fast temperature dissipation in exothermal reactions and quick removal of gases forming on the surface of the process good.

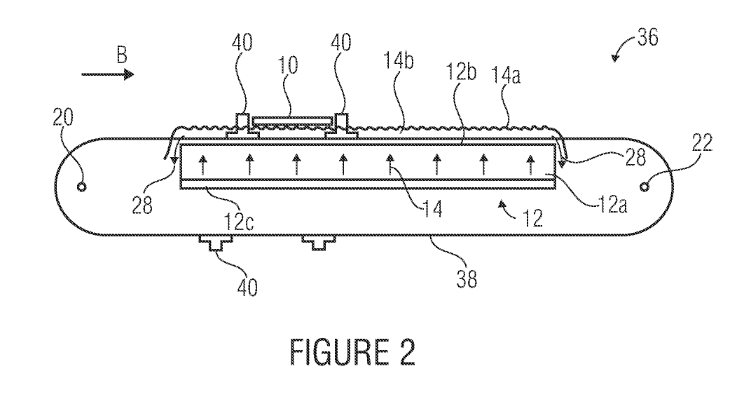

An alternative embodiment in which the process good rests on a transport system is shown in FIG. 2.

In these embodiments, the setup of the means for providing a process medium 12 may basically correspond to the setup described referring to FIGS. 1a and 1b. However, in the embodiment shown in FIG. 2, a transport means 36 is provided which comprises endless means 38 where rest elements 40 for the process good 10 are attached. Again, only schematically, some rest elements are shown in FIG. 2, wherein rest elements may be distributed over the entire length of the endless means 38. The endless means 38 in turn may be rotated around axes 20 and 22. The rest elements 40 may be configured to provide for guidance of the process good 10 in both the direction of movement B and in a direction perpendicular to the direction of movement. Again, two endless means spaced apart from each other in a direction transverse to the direction of movement, each comprising respective rest elements, may be provided.

As is shown in FIG. 2, the process good 10 is guided by the rest elements 40 such that it floats on the process medium projection 14 above the upper boundary 12b. In this embodiment where the process good 10 rests horizontally on the rest elements 40 such that it floats on the process medium, i.e. such that the top surface of the process good 10 is above the process medium level, single-side treatment of the process good is possible.

In embodiments of the invention, additionally means may be provided which supplies a liquid from above so as to wet the process good to reduce mechanical strain of the process good. In addition, means may be provided which supplies liquid from above so as to hold the process good down.

It is to be pointed out here that for reasons of illustration in particular vertical dimensions are illustrated in the Figures in an exaggerated manner. It is particularly to be kept in mind that embodiments of the invention are in particular suitable for processing or handling plate-shaped process goods of a thickness in the range of 0.2 mm.

It is additionally pointed out that, in all the embodiments of the invention, means for feeding process medium from above, such as, for example, distributor plates or spray nozzles, may be provided in addition or as an alternative to the means causing process medium to be supplied from below.

It need not be explained separately that the elements 40 in operation again accept a process good from a delivery device at the left end of the transport means and deliver the process good to an accepting device at the right end of the transport means, wherein the elements 40 move together with the process good from acceptance to delivery. The movement of the process good, caused by the rest elements 40, along the process path again is a purely horizontal movement relative to the earth's gravitational field.

The embodiment described referring to FIG. 2 also allows material to be transported carefully. In addition, a setup as has been described referring to FIG. 2 allows automatic removal of broken process goods so that this does not cause any additional silicates to form in the medium, which may result in an increased useful life of media.

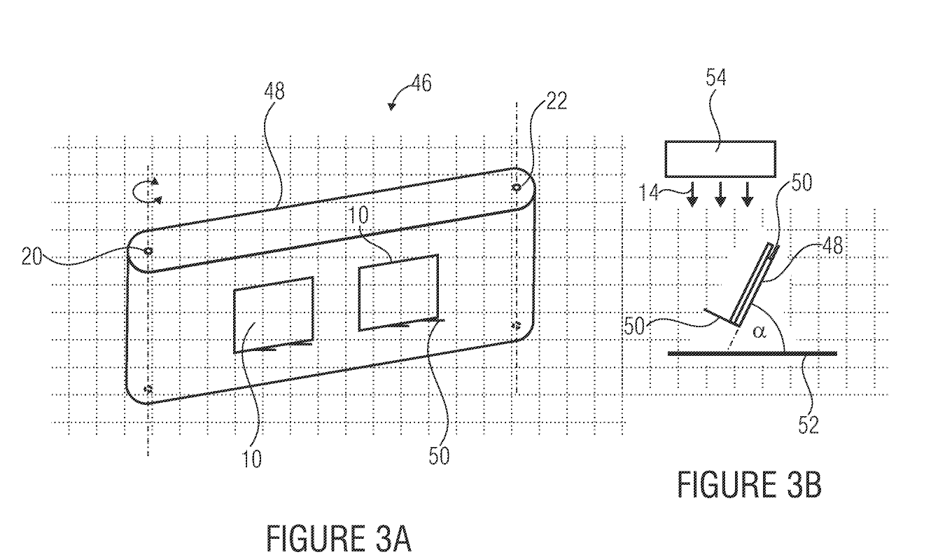

An alternative embodiment of a processing device is shown in FIGS. 3a and 3b. In this embodiment, transport means includes endless means 48 which may be rotated around two axes 20 and 22. Transport elements in the form of holders 50 on which the process good 10 may be placed in an inclined position, i.e. at an angle α to the horizontal line 52, are attached to the endless means 48. The holders 50 may be formed by longer lower pins and shorter upper pins which protrude from the endless means 48, the process good resting on the lower pins.

Means 54 is provided for providing a process medium which supplies process medium from above so as to wet at least the surface of the process good directed to the top with the process medium. The means 54 gives rise to, at least along a portion of the process path over which the transport means moves the process good, a volume into which process medium is sprayed or introduced, wherein the process good enters this volume and, thus, the process medium laterally. In addition, the holders 50 move together with the process good along the process path.

The embodiment shown in FIGS. 3a and 3b allows a space-saving setup, process good overflow from above, thereby allowing good heat removal in exothermal process and good rinsing. In addition, the setup of the transport means may be more independent of the process good format.

In embodiments, the invention may be configured to process and handle plate-shaped process goods comprising two opposite main surfaces, the device being implemented such that the main surfaces when being moved along the process path are arranged so as to be horizontal or at an angle relative to the horizontal line.

Generally, the means for providing a process medium may be formed in any manner possible as long as the transport means is able to cause the process good to enter the process medium laterally and be moved through it or be passed by same while floating on the process medium. In embodiments of the invention, the process medium providing means comprises a process medium container covered by a distributor plate. The distributor plate includes a plurality of fluid conduits through which the process medium or process liquid reaches the top face of the distributor plate when the process medium container is filled so as to overflow. This causes liquid to be pushed through the fluid conduits and a liquid projection to form on the distributor plate into which the process good may enter laterally or which the process good may be passed by while floating. Caused by the liquid flow through the fluid conduits from the bottom to the top, a buoyant force may act on the process good, which may cause the process good to float on the liquid projection which may be formed by a liquid film. Lateral boundary walls may be provided so as to prevent the process medium from flowing off laterally from the top surface of the distributor plate. In embodiments of the invention, the process medium thus only flows over on the sides which the process good passes. Alternatively, the process medium may be provided from above by a distributor plate or spray nozzles, wherein in this case the process good enters the process medium volume produced by this laterally.

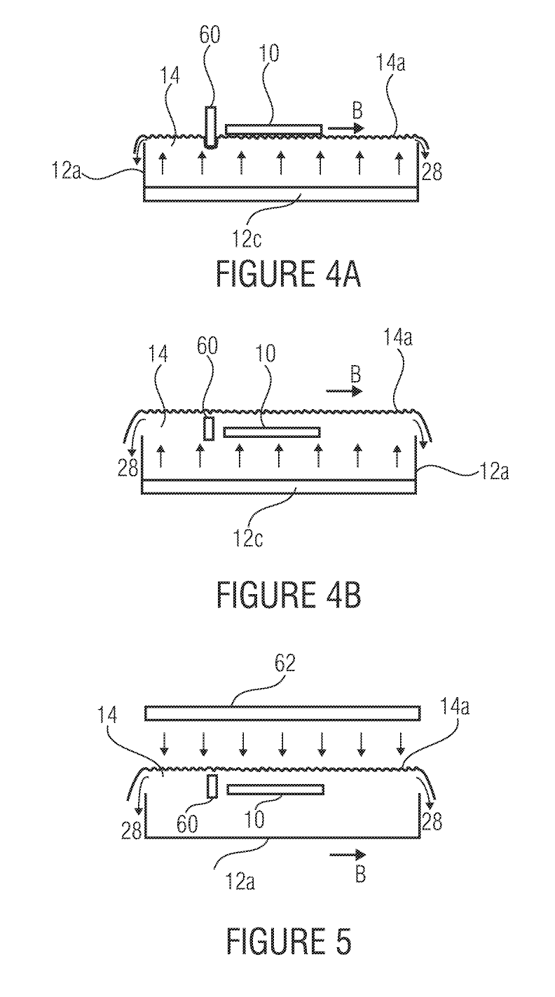

Different implementations of the means for providing the process medium are shown in FIGS. 4a to 7. In these Figures, a respective transport element is referred to schematically by the reference numeral 60 and a direction of movement of the process good is referred to by B.

In accordance with FIGS. 4a and 4b, the process medium 14 is fed to the process medium reservoir 12a by corresponding filling means 12b, as is indicated by respective arrows directed to the top. In accordance with FIG. 4a, the process good 10 is transported while floating on the process medium level 14a, whereas in accordance with FIG. 4b the process good 10 is transported below the process medium level 14a.

In the embodiment shown in FIG. 5, the process medium 14 is fed into the process medium reservoir 12a using process medium providing means 62 arranged above the process path such that same flows over at the, in the direction of movement B, front and back ends, see arrows 28. The process medium providing means 62 may exemplarily be implemented by a distributor plate or by spray nozzles. Thus, the medium level 14a is above the process good 10. When feeding from above, which is schematically indicated by the arrows directed downwards in FIG. 5, it is possible to omit hold-down elements, since the process good can be held down by the process medium flow from above. Thus, shadowing on the surface of the process good can be avoided completely. Additionally, in the embodiment shown in FIG. 5, the process medium may also be fed from below.

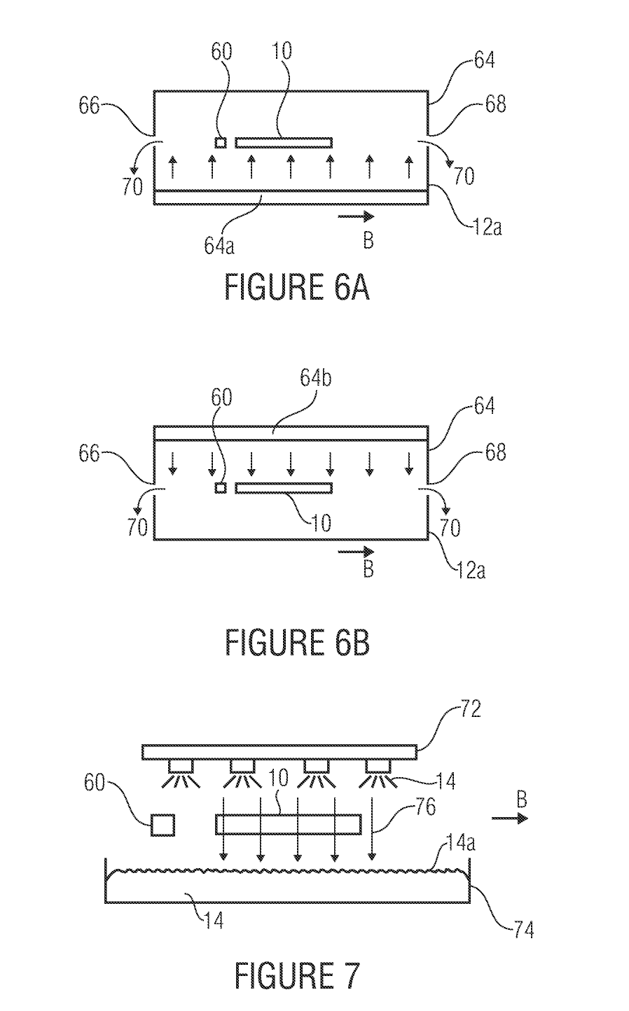

FIGS. 6a and 6b show an alternative embodiment including a closed medium reservoir 64 which comprises an inlet opening 66 in a, in the direction of movement B, back wall and an outlet opening 68 in a, in the direction of movement, front wall, schematically. The inlet opening 66 and the outlet opening 68 allow the process good 10 and the transport element 60 to move through the medium reservoir. Filling the medium reservoir which results in an overflow 70 through the inlet opening 66 and the outlet opening 68 may be done by filling means 64a from below (FIG. 6a) or by filling means 64b from above (FIG. 6b).

In embodiments, a wet process chamber which represents a device for providing a process medium may be implemented to be an overflow tank, the surface of the process good being positioned below the liquid level. The process good may enter through a slot into the tank the cross-section of which is small enough so as to only let through part of the liquid volume circulating. The orientation of the flow direction in the inner tank can provide for the process good to be kept below the liquid, exemplarily by a flooding tank from above.

FIG. 7 finally shows an embodiment in which process medium providing means 72 is provided above the process path along which the process good 10 is moved in the direction of movement B. A process medium reservoir 74 as an accepting container is provided below the process path. The process medium providing means 72 may be implemented to be a distributor plate or a nozzle plate and is configured to emit the process medium downwards such that a process medium volume which is indicated in FIG. 7 by the arrows bearing the reference numeral 76 is produced. The process good 10 enters this process medium volume 76 laterally when moving in the direction of the arrow B. Instead of the horizontal position shown in FIG. 7, in this embodiment, the process good may also be positioned to be inclined, as has been discussed above referring to FIGS. 3a and 3b. In the embodiment shown in FIG. 7, the process good is positioned in the medium reservoir 74 above the medium level. High flow-through, heat dissipation in exothermal reactions and good rinsing can be achieved here.

There is no need for explaining in detail that means for feeding overflowing process medium back to the respective filling means may be provided in embodiments of the invention. Equally, in the embodiment shown in FIG. 7, means may be provided for feeding back process medium from the process medium reservoir 74 to the means 72. Additionally, means may be suitably provided for treating the process medium again before it is returned.

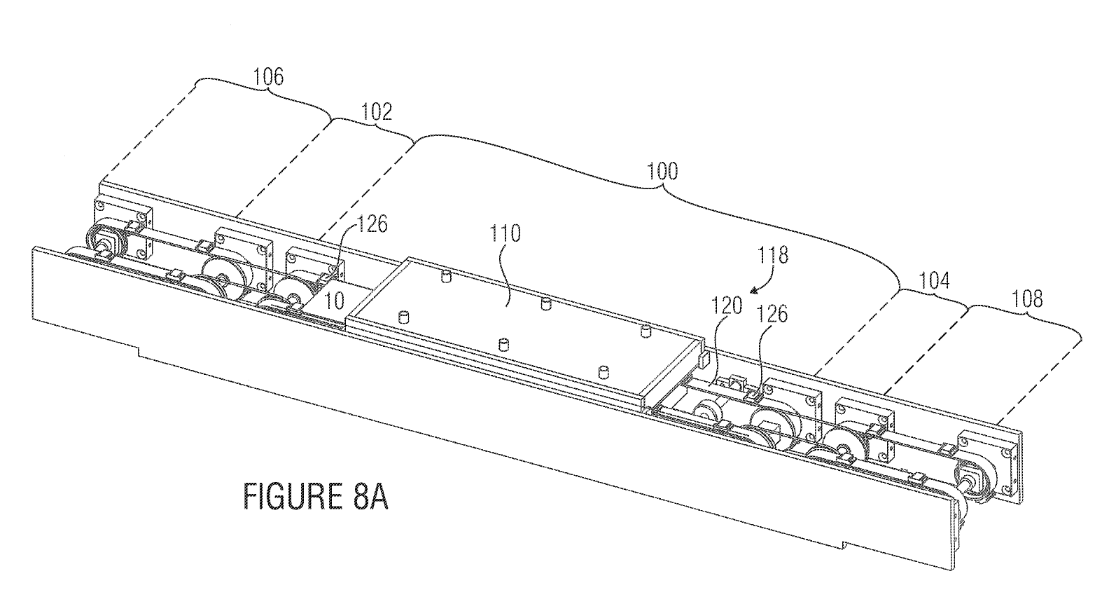

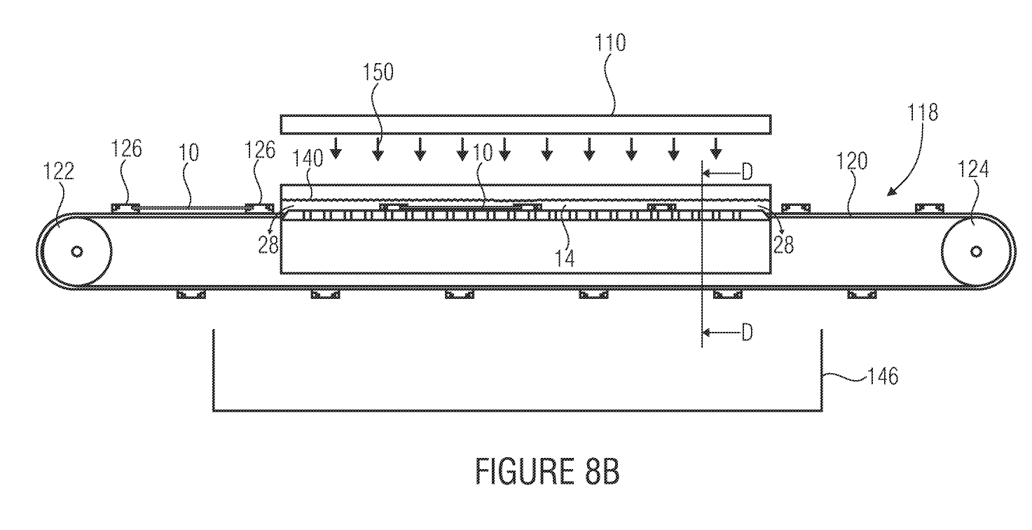

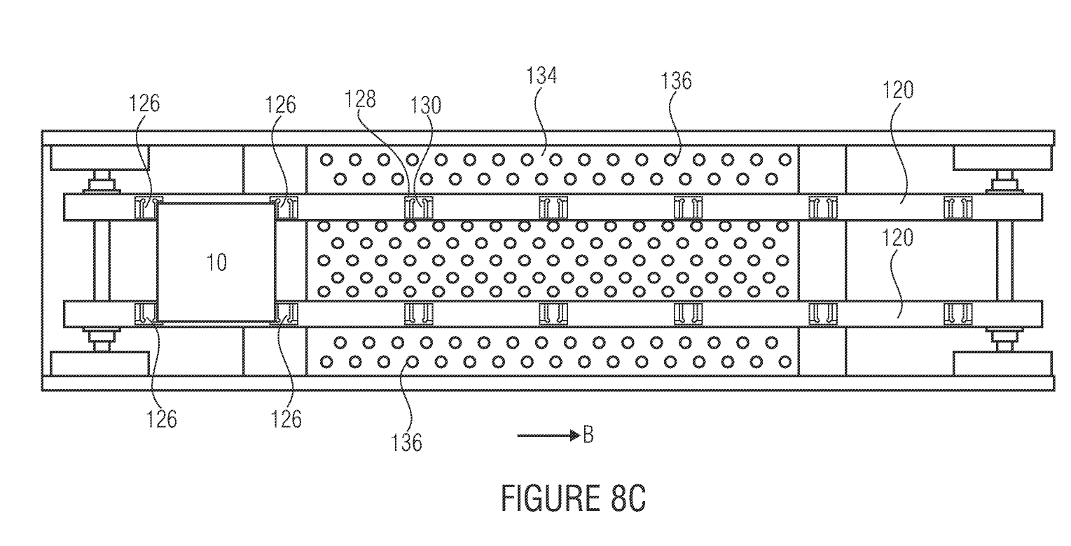

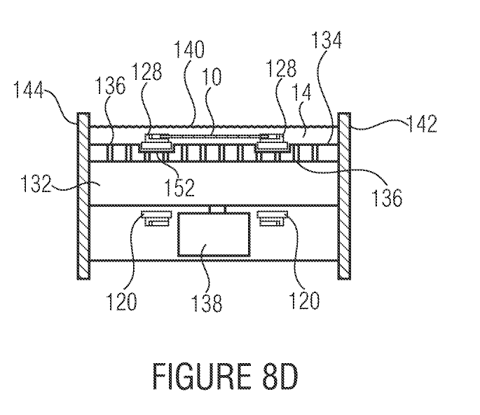

An embodiment of an inventive processing device which generally operates following the principle shown in FIG. 2a will be discussed subsequently referring to FIGS. 8a to 8d.

FIG. 8a shows a perspective view of a system comprising an inventive processing device 100, a delivery device 102 and an accepting device 104. Additionally, a processing stage 106 upstream of the delivery device 102 and a processing stage 108 downstream of the delivery device 104 are shown schematically. FIG. 8b shows a schematic side view of the processing device 100, and FIG. 8c shows a schematic top view thereof, however without wetting means 110 which is arranged above the process path. FIG. 8d finally shows a schematic sectional view along the line D-D in FIG. 8b. It is to be mentioned here that the Figures all show those feature considered to be needed for describing the invention, wherein, however, not all of the features are illustrated in the respective views so as not to overload same.

The processing device 100 includes transport means having two endless belts 120 which are movable via rolls 122 and 124 positioned on axes. Rest elements for a process good 10 exemplarily in the form of a poly-crystalline or mono-crystalline semiconductor wafer are attached to the endless belts 120. Four respective rest elements 126 receive one semiconductor wafer 10. As can be seen best in FIG. 8c, rest elements 126 are distributed over the endless belts 120 such that semiconductor wafers 10 may be transported individually one after the other. The rest elements 126 may be configured to guide the semiconductor wafer both in the direction of movement B and transverse to the direction of movement. For this purpose, the rest elements may comprise lateral projecting regions 128 which determine the position of the wafer 10 transverse to the direction of movement. In addition, the rest elements 126 comprise a higher central region 130 which forms a front and back stop for a respective wafer. In order to allow careful handling of the wafer and keep shadowing regions as small as possible, the rest area on which the wafer 10 rests may be beveled.

A suitable drive motor (not shown) may be provided to drive one of the axes on which the rolls 122 and 124 are arranged so as to drive the endless belts 120 and, thus, the rest elements 126.

Additionally, the processing device includes means for providing the process medium. In the embodiment illustrated, this means includes the wetting means 110 already mentioned which is arranged above a process path along which the wafers 10 are moved. The process medium providing means additionally includes a process medium container 132 (FIG. 8d) covered by a perforated plate 134. Openings 136 through which process medium may pass from the process medium reservoir 132 to the top of the perforated plate 134, may be provided in the perforated plate 134. Means 138 for filling the medium reservoir 132, such that process medium passes through the openings 136 to the top of the perforated plate 134 so as to reach a process medium projection 140 as is shown in FIG. 8d, is illustrated schematically in FIG. 8d.

As can be gathered from FIG. 8d, lateral overflow of the process medium projection 140 is avoided by lateral walls 142 and 144. The process medium only flows over at the, in the direction of movement B, front and back ends of the perforated plate 134, i.e. of the medium reservoir 132, as is shown in FIG. 8b by corresponding arrows 128. The overflowing medium may be collected in a collecting container 146 and be used again for filling the process medium reservoir by suitable feedback means (not shown) using the filling means 138. The filling means 138 may exemplarily comprise a plurality of fluid lines which lead into the process medium reservoir 132 and through which the process medium can be introduced into the process medium reservoir 132 by means of corresponding pump means.

In operation, the process medium reservoir 132 is filled with the process medium, such as, for example, an etch solution for a semiconductor wafer, such that a process medium projection is produced on the top surface of the perforated plate 134. A wafer is moved through this liquid projection using the transport means, in particular the rest elements 126, the wafer 10 entering the process medium projection 140 from the left-hand side. The movement of the wafer, caused by the transport means and, in particular, the endless belt 120 and the rest elements 126, along the process path through the process medium projection 140 is a movement purely horizontal relative to the earth's gravitational field. Thus, the wafer can be processed by the process medium in a manner that handles the material with care.

In the embodiment illustrated in FIGS. 8a to 8d, as a supportive measure, a process medium is provided from the top by the wetting means 110 which may comprise spray nozzles through which the process medium is fed from above, as is indicated in FIG. 8b by the arrows 150. This wetting allows destroying the surface tension of the medium and floating can be prevented so that no hold-down systems are necessary and there is no shadowing on the surface of the process good. As can be gathered from FIG. 8d, the endless belts in the embodiment shown travel to recesses 152 in the top of the perforated plate 134, thereby causing the process good 10, such as, for example, the semiconductor wafer, to be transported closer to the top surface of the perforated plate 134.

In embodiments of the invention, the process good, such as, for example, the wafers or substrates, may thus be placed on a transport device, such as, for example, a chain or belt system with a positioning system for the wafers attached thereto. The transport speed may basically be the same at every position throughout a system comprising several stages, wherein the level of the wafer may also be nearly equal in the entire system. Zones between different operating stages, for example between etching and cleaning or drying, may be realized by a roll or O-ring system.

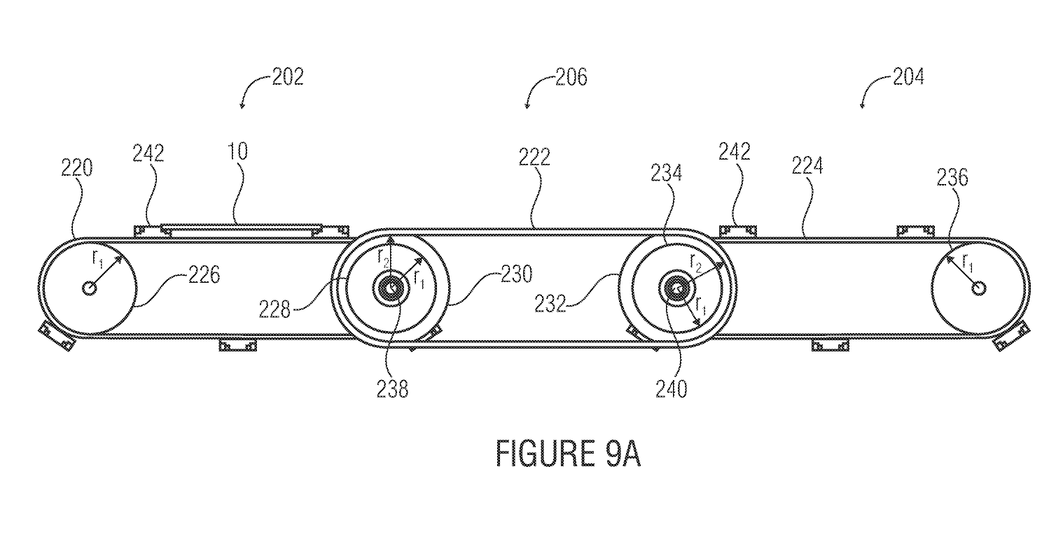

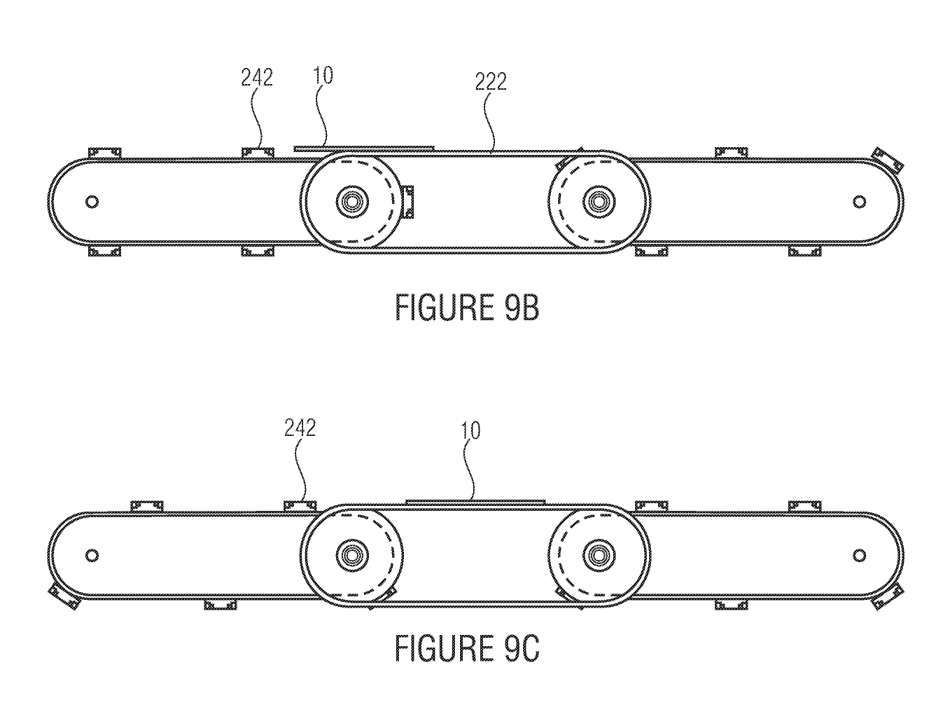

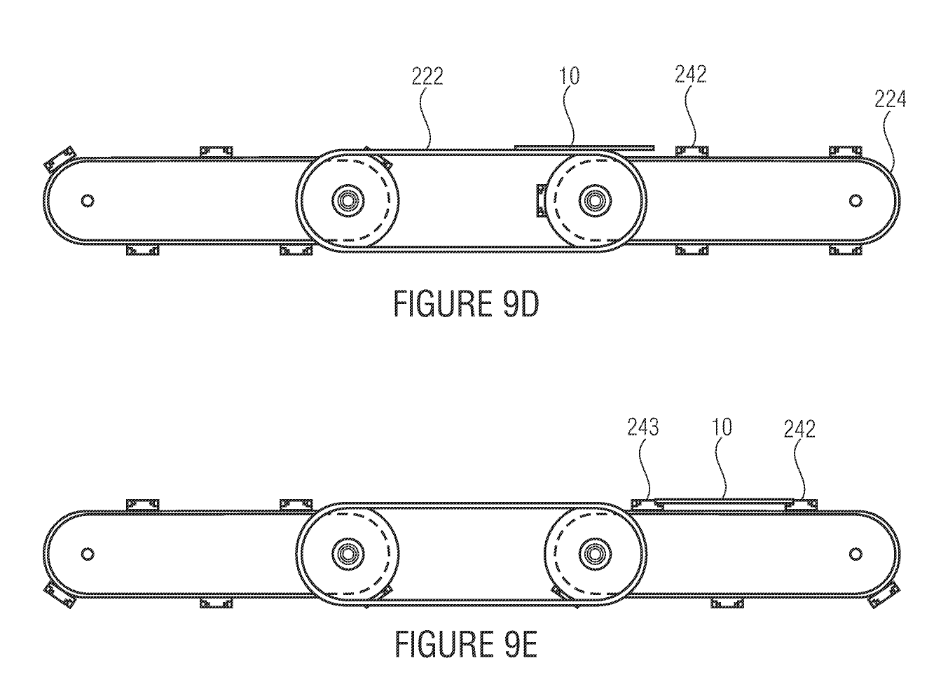

In embodiments of the invention, cleaning or etching of the process good may be performed in the processing device, depending on which process medium is provided. Further processes may be performed in upstream or downstream operating stages, as is shown schematically in FIG. 8a at 106 and 108. An intermediate transport system which will be discussed in greater detail below referring to FIGS. 9a to 9e may be used for bridging between different processing stages in a system in embodiments of the invention.

FIG. 9a shows a first processing device 202, a second processing device 204 and an accepting/delivery device 206. The processing devices 202 includes an endless belt 220, the accepting/delivery device 206 comprises an endless belt 222 and the processing device 204 comprises an endless belt 224. Exemplarily, the devices 202, 204 and 206 shown in FIG. 9a may be implemented by the processing device 100, the accepting device 104 and the downstream processing stage 108 shown in FIG. 8a.

The endless belt 220 travels over rolls 226 and 228 at a radius r1. The endless belt 222 travels over rolls 230 and 232 at a radius r2. The endless belt 224 travels over rolls 234 and 236 at a radius r1. The rolls 228 and 230 are positioned on a same axis 238 and the rolls 232 and 234 are positioned on a same axis 240. One of the axes may be driven by a motor (not shown) so as to move all the endless belts 220, 222 and 224 at the same time.

The processing devices 202 and 204 may comprise corresponding rests 242 for transporting a process good 10 through a process path. As an alternative to the form shown, the rests may of course also be of a different form. The endless belt 222 has no rest elements and is made of a material cooperating in terms of friction with the process good so as to allow same to be taken along. Exemplarily, the endless belt 222 may be formed by a round belt made of a suitable material, such as, for example, a polymer.

The radius r2 is greater than the radius r1, so that, in correspondence with the gear ratio caused by this, the endless belt 222 rotates faster than the endless belt 220 and the endless belt 224.

The ratio of the two radii relative to each other is set such that the endless means 22 will move the process good from a track of travel of the transport element around the axis 238 or the roll 228 at such a speed that the process good does not interfere in the movement of the successive rest element 242 around the axis 238. A respective delivery of the process good, which may again be a poly-crystalline or mono-crystalline semiconductor wafer, is shown in FIGS. 9b to 9e. In accordance with FIG. 9b, the process good is in frictional engagement with the endless belt 222 which, as can be recognized in FIG. 9, moves the process good 10 away faster than the rest element which here is referred to by the reference numeral 242, follows. In accordance with FIG. 9c, the process good 10 is already outside the track of travel of the rest element 242 around the roll 228 such that this element, when moving around the roll 228, can no longer meet the wafer 10.

FIGS. 9d and 9e show the situation when delivering the wafer from the accepting/delivery device 206 to the following processing device 204. As has been explained above, the endless belt 222 moves faster than the endless belt 224. This means that the process good catches up with the rest element referred to here by the reference numeral 242 and abuts on the central elevation thereof. After abutting, the process good 10 can no longer move at the speed of the endless belt 222, but only at the speed of the endless belt 224. Since the wafer 10 is only in frictional engagement with the endless belt 222, slipping between same may take place. Delivery from the accepting/delivery device 206 to the processing device 204 is finished when the back rest element that is referred to by the reference numeral 243 in FIG. 9e has finished its circular movement about the roll 234 (FIG. 9a) and is engaged with the process good 10. This situation is illustrated in FIG. 9e.

Embodiments of the present invention thus include an accepting device (accepting/delivery device 206) which allows a higher speed of the process god transported than the previous processing device. This is, in accordance with the invention, realized in a particularly easy manner by the fact that the endless means of the delivery device and the accepting device travel around the same axis at different radii so that the endless means of the accepting device moves faster. This allows safely removing the process good from a track of travel of a following pusher element before same tips downwards and could meet the process good.

The procedure described referring to FIGS. 9a to 9e is suitable for all the systems in which a transport element follows a process good and, after delivery to an accepting device, turns around an axis.

By using intermediate transport systems, exemplarily the accepting/delivery device 206, medium regions of upstream and downstream processing devices can be separated. In addition, the transport sections can be separated so that media can be prevented from being carried over from the processing stages. In addition, less material wearing of the transport system and synchronization of individual process transport sections can be achieved. It is also possible to use different materials for the individual transport sections.

As an alternative to the embodiments described, higher speed of an intermediate transport system may also be implemented using different means, exemplarily using a gear ratio via chains, gears, transmission, racks and the like. In addition, different drive systems and motors, which would then have to be synchronized, may be used. Intermediate transport systems may additionally be realized using rolls, bands, O-rings and the like.

Apart from a basically purely horizontal movement along a process path in a processing device, embodiments of the present invention thus also allow a basically horizontal movement of the process good through an entire system. With reference to FIGS. 9a to 9e, it may also be taken into consideration that the differences of the radii between the rolls of the processing devices and the accepting/delivery device can be reduced or compensated using the height of the rest elements. Embodiments of the present invention thus allow a basically horizontal movement through a processing system having several stages, wherein a basically horizontal movement exemplarily means a movement having a vertical component of no more than 5 mm.

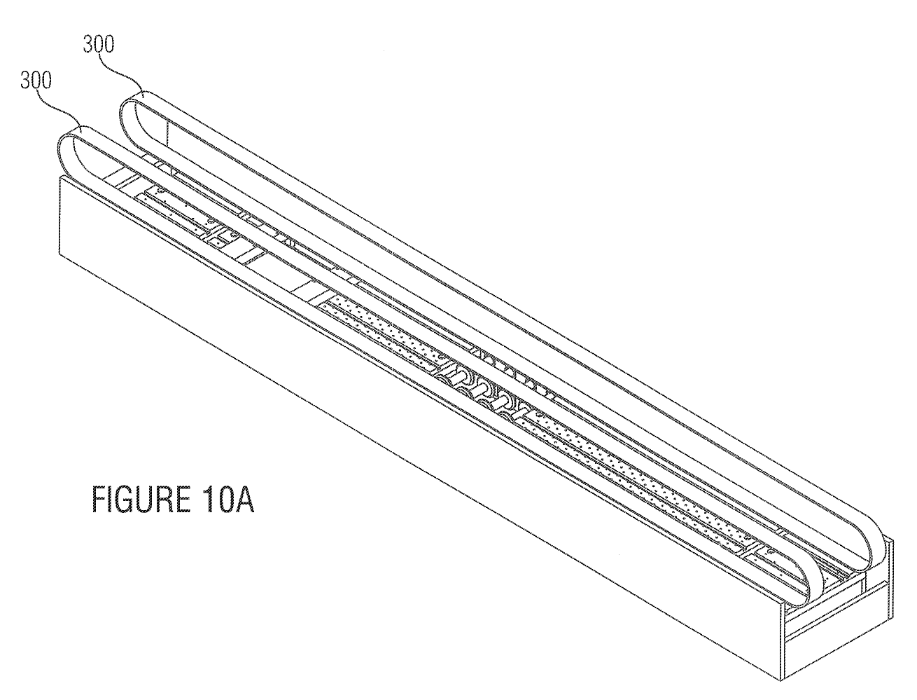

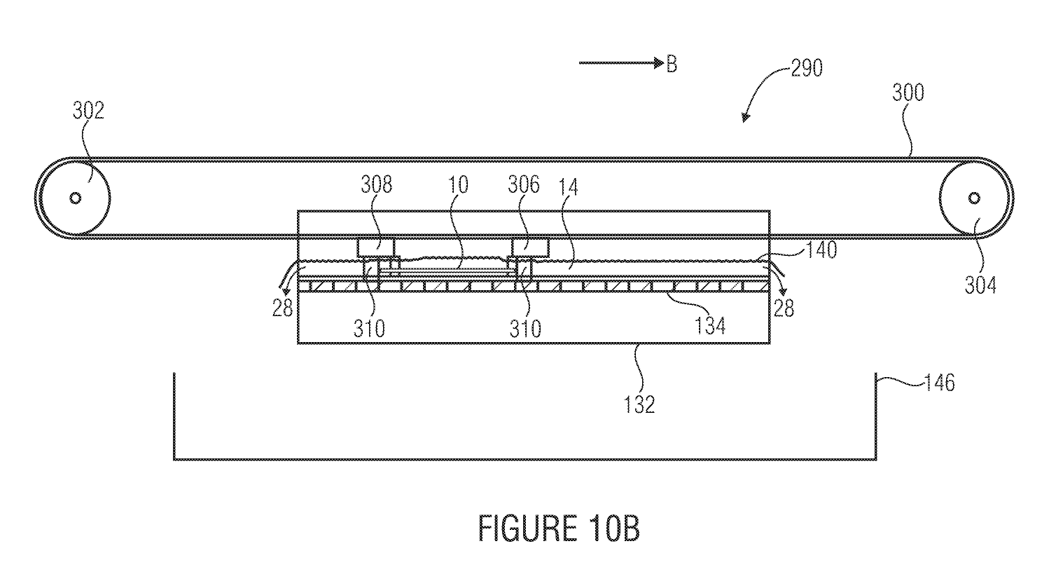

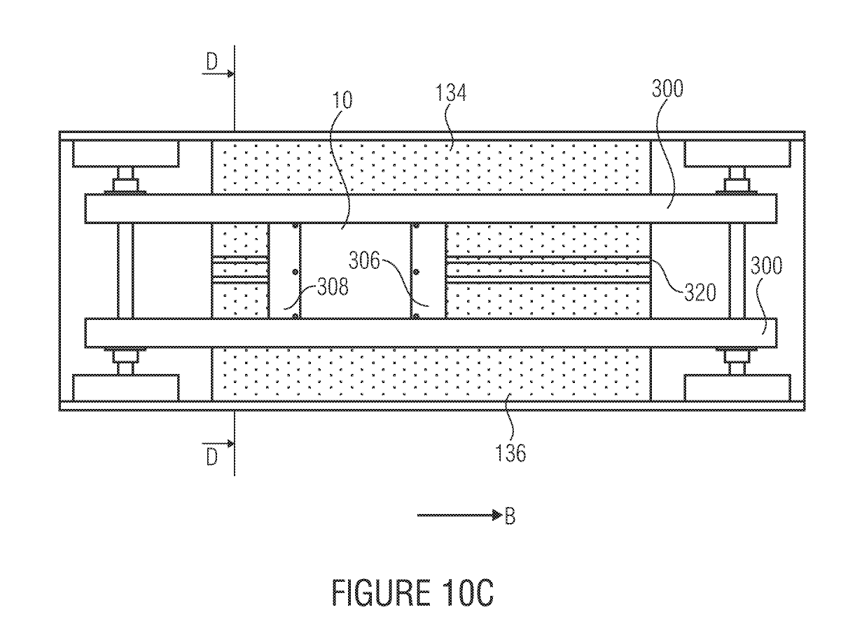

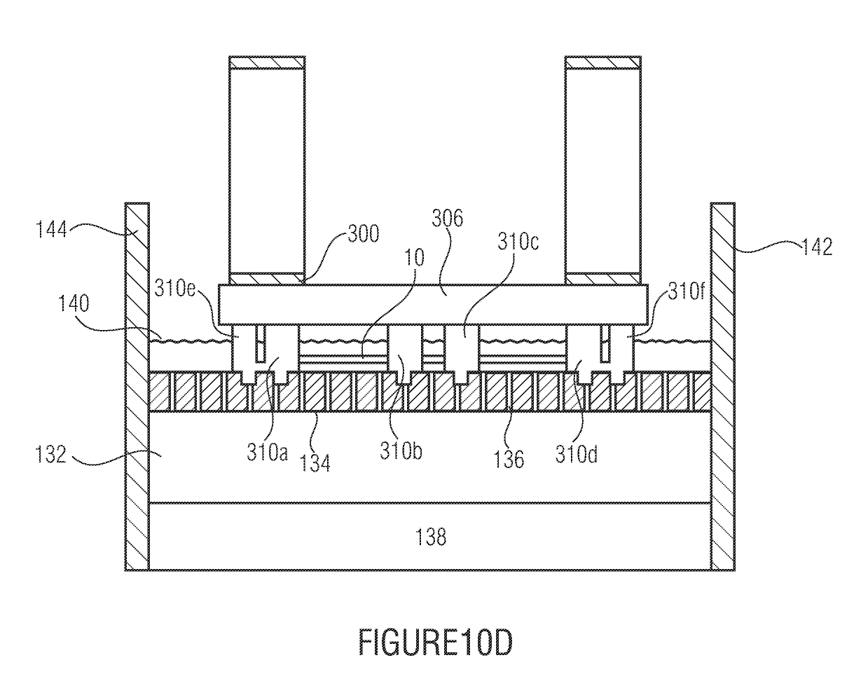

Another embodiment of the invention which operates in correspondence with the principle described above referring to FIG. 1a will be described subsequently referring to FIGS. 10a to 10d. FIG. 10a illustrates a schematic perspective view, FIG. 10b schematically illustrates a side view in which, however, elements which would be covered by a lateral wall of the process medium reservoir can be recognized, FIG. 10c illustrates a top view, and FIG. 10d represents a sectional view along a line D-D in FIG. 10c.

In the embodiment shown in FIGS. 10a to 10d, a driving device includes two endless belts 300 traveling around rolls 302 and 304. Two connecting carriers 306 and 308 are attached to the endless belts 300 spaced apart from each other. Transport elements which in FIG. 10b are generally referred to by the reference numeral 310 which allow transport and guidance of the process good 10 project from connection carriers 306 and 308. Four transport elements 310a, 310b, 310c and 310d which are attached to the transport element 306, by means of which the process good 10 can be pushed in the direction of movement B, are shown in FIG. 10d. In addition, transport elements which allow lateral guidance of the process good may be provided, as is shown in FIG. 10d, by the two elements 310e and 310f. This means that the position of the process good in the direction of movement and transverse to the direction of movement (i.e. in the X direction and in the Y direction) can be determined by the corresponding elements. Additionally, suitable hold-down elements for the process good may be attached to the connection carriers 306.

The endless belts may be driven in connection with the transport elements attached thereto using suitable driving means, such as, for example, a motor (not shown) which drives one of the axes of the rolls 302 and 304 so as to move the process good along a process path from being accepted by a delivery device to being delivered to an accepting device.

A process medium providing device in this embodiment may be of a setup comparable to the setup of the process medium providing device described referring to FIGS. 8a to 8d. Same elements here are referred to by the same reference numerals and need not be discussed further. In any case, the means for providing the process medium is again configured to produce a process medium projection 140 above the top surface of the perforated plate 134 such that the process good 10 can be introduced into the process medium projection laterally by means of the transport elements which move along the process path together with the process medium.

As can be particularly gathered from FIGS. 10c and 10d, grooves 320 which projections of the transport elements 310a to 310f engage are provided in the top surface of the perforated plate 134 comprising the openings 136. This allows advantageously using these elements, for example when same do not transport any wafers for processing, to remove broken wafer parts from the process path.

In embodiments of the invention, the process good, for example the wafer or the substrate, is placed on a perforated plate and floats on a liquid film which is pressed through the holes of the perforated plate. A transport device here can push the process good over the perforated plate. This transport device can also immerse the process good below the surface of the process medium or process liquid. Zones between different processing stages, exemplarily between etching and cleaning or drying, may be realized using roll, air cushion or O-ring systems. The transport device may exemplarily be realized using a chain or a belt.

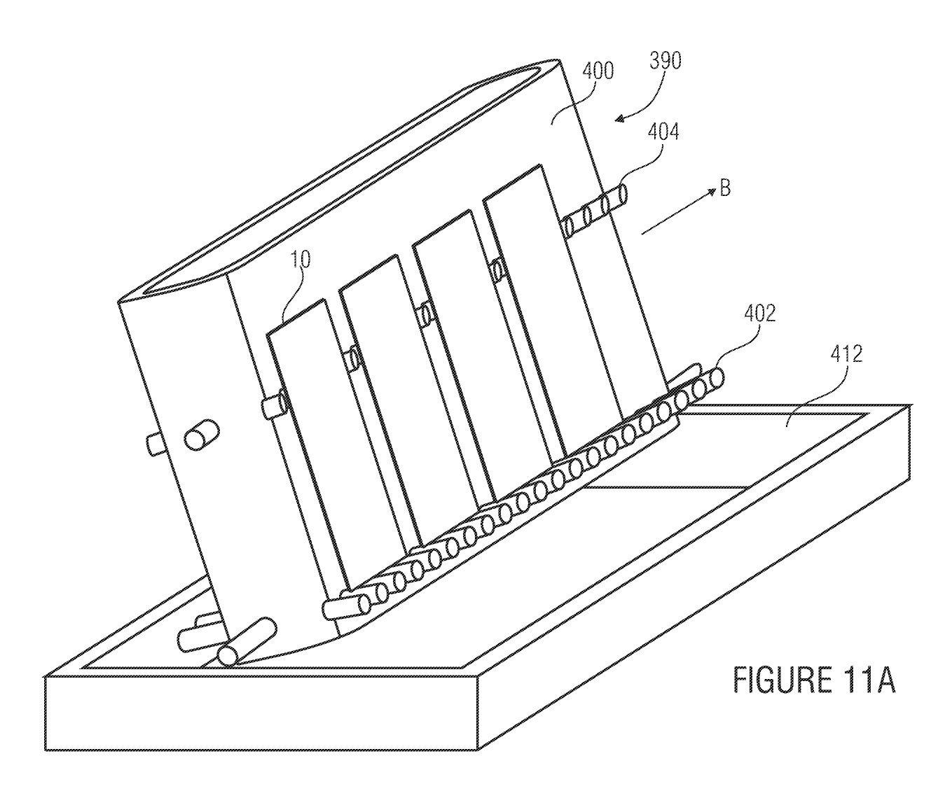

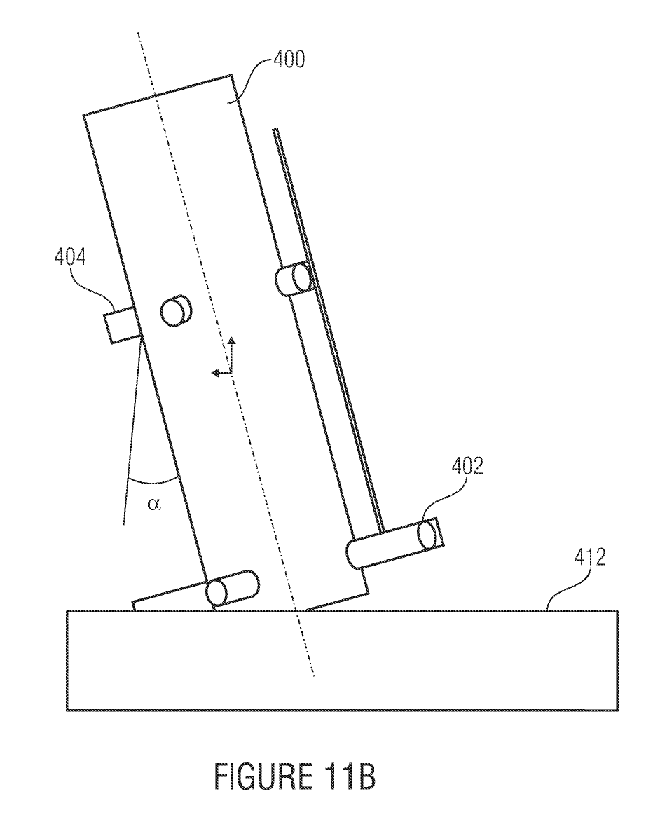

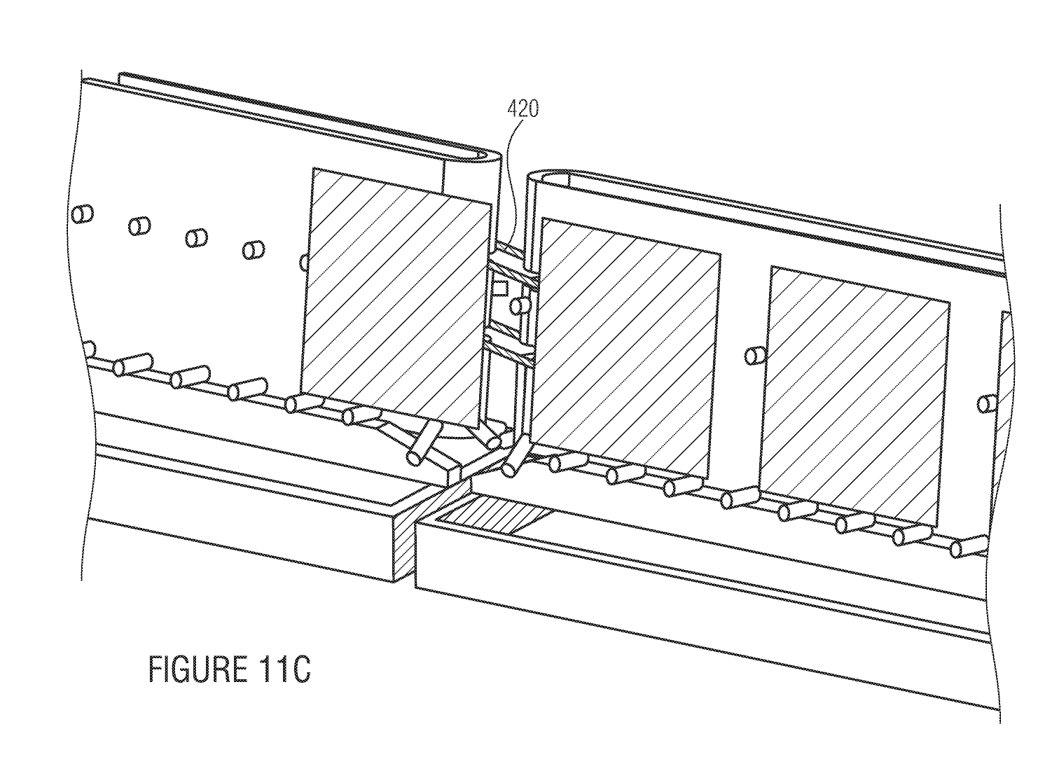

An embodiment of driving means of another embodiment of an inventive processing device which is based on the principle already described above referring to FIGS. 3a and 3b will be discussed below referring to FIGS. 11a to 11c.

The transport means shown in FIGS. 11a and 11b comprises an endless belt 400 to which hold elements in the form of pins 402 and 404 are attached. The pins 402 may be implemented to be longer than the pins 404, wherein the process good may be positioned while resting on several of the pins 404 and leaning on the pins 402. The endless belt 400 is arranged at an angle α relative to the vertical line, as can particularly be gathered from FIG. 11b. A process good or several process goods 10 can be processed individually one after the other by being placed on the pins 202 such that they are held in an inclined orientation, as can be gathered from FIGS. 11a and 11b. The pins 402 and 404 thus act as a transport element which is moved along a process path together with the process good.

Not shown in FIGS. 11a and 11b is process medium providing means which is arranged above the process path through which the process good is moved, as discussed before referring to FIG. 3b. A collecting reservoir for the process medium is schematically shown in FIGS. 11a and 11b at 412. By the driving means shown in FIGS. 11a and 11b, the process good may be introduced laterally into a process medium volume produced by the process medium providing means arranged above the process path.

FIG. 11c schematically shows one way for process goods to travel between two processing stages of a setup, as is shown in FIG. 11a. As is shown in FIG. 11c, such a delivery between corresponding devices may be done using O-rings.

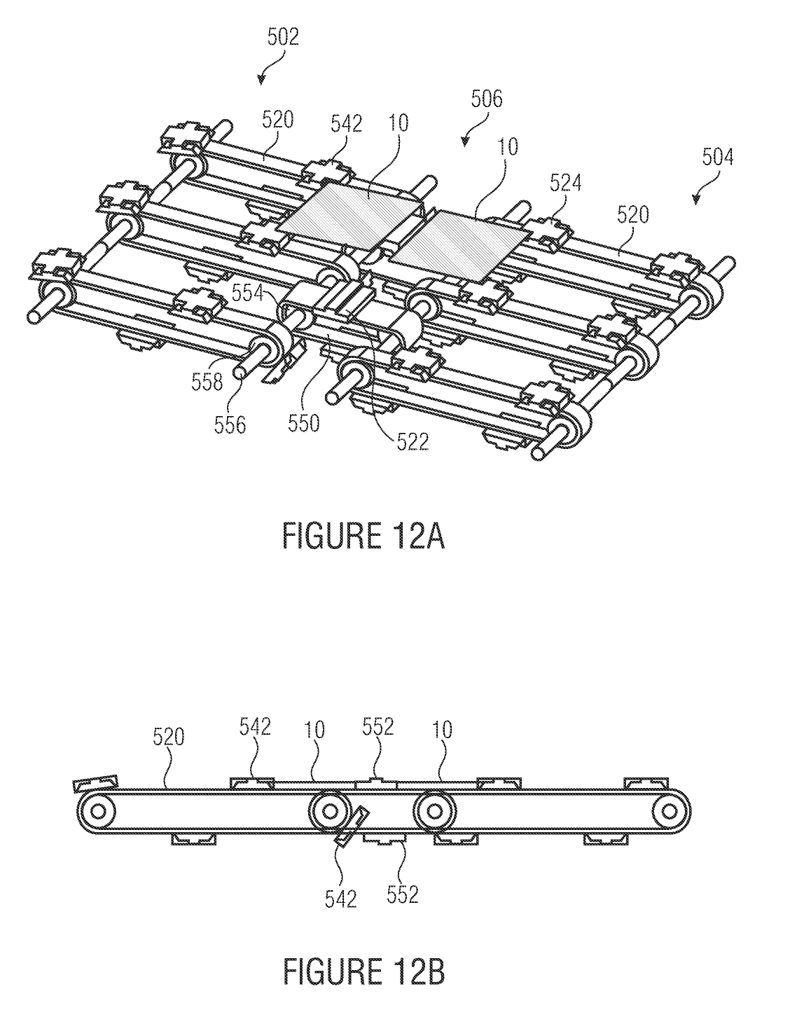

FIGS. 12a and 12b show an embodiment of an accepting/delivery device which may be employed in inventive devices for processing a process good. When increased speed of an accepting/delivery device, as has been discussed referring to FIGS. 9a to 9e, is not necessary, instead an accepting/delivery device, as is shown in FIGS. 12a and 12b, may be used. FIGS. 12a and 12b schematically show a first processing device 502, a second processing device 504 and an accepting/delivery device 506. The processing devices each comprise three endless devices 520, such as, for example, endless belts or endless chains, arranged next to one another. The endless belts are each provided with rest elements 542, in the manner shown in FIGS. 12a and 12b, for accepting a process good 10 to be handled, such as, for example, semiconductor wafers. As is shown in FIGS. 12a and 12b, the rest elements 542 comprise recesses at each corner thereof so as to allow process goods to be accepted one after the other (in the direction of the course of the endless devices 520) and also next to one another. In embodiments of the invention, rest elements may thus comprise a cross-shaped elevation by which the rest regions or stops for four process goods, such as, for example, semiconductor wafers, in the rest elements 542 are implemented.

The accepting/delivery device 506 in the embodiment shown in FIGS. 12a and 12b includes an endless belt 550 which exemplarily comprises two rest elements 552. The rest elements 552 comprise a central elevation which defines two rest areas for a front and a back process good. The elevation serves as a stop for a back process good and as a pusher for a front process good.

Rolls 554 on which the endless belt 550 of the accepting/delivery device 506 travels are attached to an axis 556 which rolls 558 on which the endless belts 520 travel are also attached to. The endless devices 550 of the accepting/delivery device 506 here engage between the endless devices 520 of the processing devices 502 and 504.

When the first processing device 502 transports a process good 10 in a clockwise direction in a direction towards the accepting/delivery device 506, the front end of the process good will come to rest on a corresponding recess of the rest element 552. The rest elements 542 of the first processing device 502 then continue to push the process good until disengaging with the process good. When this is the case, the elevation of the second rest element 552 engages the back edge of the process good and continues to push the process good such that same becomes engaged with the recesses of the rest elements 542 of the second processing means 504, as is shown for the right process good 10 in FIGS. 12a and 12b. The process good 10 is then continued to be pushed by the rest element 552 until the subsequent rest elements 542 of the front processing device become engaged with the back edge of the process good 10. They continue to push the process good 10 such that the rest elements 552 may tip downwards.

In the embodiment of an accepting/delivery device shown in FIGS. 12a and 12b, rest elements 552 engage the process good 10 in a central position, while the rest elements 542 of the processing devices engage the process good 10 at the outer corners thereof.

As may also be gathered from FIGS. 12a and 12b, the rest elements may comprise beveled regions so as to allow smooth engagement of the process good 10.

In embodiments of the invention, the process device may carry the process good to a section comprising a spray system so that liquid is sprayed or flooded onto the surface, wherein at the same time liquid can be flooded from below, and wherein the liquid can be re-circulated from an overflow tank to the spray system.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A device for processing a process good with a process medium, comprising:
a provider for providing the process medium; and
a transporter comprising a transport element configured to move the process good along a process path between being accepted by a delivery device and being delivered to an accepting device so as to move with the process good from being accepted to being delivered, wherein the device is configured such that the process good enters the process medium laterally and is moved through same or passed by same while floating on the process medium,
wherein the provider for providing the process medium comprises:
a process medium reservoir covered by a plate, the plate comprising a top surface, and the plate being perforated by a plurality of openings, and
a filler for filling the process medium reservoir such that the process medium reservoir overflows and thereby the process medium is driven through the openings onto the top surface.

2. The device in accordance with claim 1, wherein the movement of the process good, caused by the transport element, along the process path is a movement purely horizontal relative to the earth's gravitational field.

3. The device in accordance with claim 1, wherein the transport element comprises a pusher element configured to push the process good along the process path.

4. The device in accordance with claim 1, wherein the device for providing a process medium comprises the process medium reservoir and a refiller for the process medium reservoir configured to produce a process medium projection above an upper boundary of the process medium reservoir above which the process good is fed, on which or through which the process good is moved.

5. The device in accordance with claim 1, wherein the transport element is configured to move the process good along the process path while floating on the process medium.

6. The device in accordance with claim 5, wherein the provider for providing the process medium is configured to provide a process medium film on which the process good may be moved while floating.

7. The device in accordance with claim 1, wherein the transporter is configured to move the process good through the process medium such that two opposite surfaces of the process good are wetted by the process medium at least in sections.

8. The device in accordance with claim 1, wherein the provider for providing the process medium further comprises a provider for providing the process medium from a position above the process path.

9. The device in accordance with claim 8, wherein the provider for providing the process medium from a position above the process path comprises a distributor plate comprising openings through which the process medium is provided, and/or spray nozzles for providing the process medium.

10. The device in accordance with claim 1, additionally comprising a lateral guider so as to limit movement of the process good transverse to the process path.

11. The device in accordance with claim 1, further comprising a hold-down element configured to hold the process good in a vertical direction on or in the process medium.

12. The device in accordance with claim 11, wherein the hold-down element comprises pins, T-shaped pieces or nozzles spraying onto the process good from above.

13. The device in accordance with claim 1, wherein the transporter comprises rest regions for the process good configured to move with the process good from being accepted to being delivered.

14. The device in accordance with claim 13, wherein the rest regions are configured to hold the process good in an inclined position.

15. The device in accordance with claim 1, configured for processing a plate-shaped process good comprising two opposite main surfaces, the device being configured such that the main surfaces, when moving along the process path, are arranged horizontally or at an angle relative to the horizontal line.

16. The device in accordance with claim 1, configured for processing plate-shaped semiconductor wafers or glass panels.

17. The device in accordance with claim 1, wherein the transporter comprises a circulating endless element to which one or several transport elements are attached.

18. A system for processing a process good with a process medium, comprising:
a processing device comprising a device for processing a process good with a process medium, comprising: a provider for providing the process medium; and a transporter comprising a transport element configured to move the process good along a process path between being accepted by a delivery device and being delivered to an accepting device so as to move with the process good from being accepted to being delivered, wherein the device is configured such that the process good enters the process medium laterally and is moved through same or passed by same while floating on the process medium, wherein the provider for providing the process medium comprises: a process medium reservoir covered by a plate, the plate comprising a top surface, and the plate being perforated by a plurality of openings, and a filler for filling the process medium reservoir such that the process medium reservoir overflows and thereby the process medium is driven through the openings onto the top surface; and at least either
a delivery device configured to feed the process good for being accepted by the processing device; or
an accepting device configured to accept the process good from the processing device.

19. The system in accordance with claim 18, comprising several processing devices comprising a device for processing a process good with a process medium, comprising: a provider for providing the process medium; and a transporter comprising a transport element configured to move the process good along a process path between being accepted by a delivery device and being delivered to an accepting device so as to move with the process good from being accepted to being delivered, wherein the device is configured such that the process good enters the process medium laterally and is moved through same or passed by same while floating on the process medium, wherein the provider for providing the process medium comprises: a process medium reservoir covered by a plate, the plate comprising a top surface, and the plate being perforated by a plurality of openings, and a filler for filling the process medium reservoir such that the process medium reservoir overflows and thereby the process medium is driven through the openings onto the top surface, and at least an intermediate transport device for accepting the process good from a first processing device and for delivering the process good to a second processing device.

20. The system in accordance with claim 18, wherein the delivery device, the accepting device and/or the intermediate transport device is/are configured to allow the process good to be transported on an air cushion.

21. The system in accordance with claim 18, wherein the transporter of the processing device comprises a first endless element to which the transport element is attached, for transporting the process good to a delivery region where the endless element travels around an axis at a first radius,
wherein an accepting device comprising a second endless element for accepting the process good in the delivery region and for transporting the process good from the delivery region is provided, the second endless element traveling around the axis at a second radius such that the second endless element moves faster than the first endless element,
wherein the ratio between the first and second radii is such that the second endless element moves the process good from a track of travel of the transport element around the axis at such a speed that the process good does not interfere in the movement of the transport element around the axis.

22. A method for processing a process good with a process medium, comprising:
accepting the process good by a processing device from a delivery device;
providing the process medium by means of a process medium reservoir covered by a plate, the plate comprising a top surface, and the plate being perforated by a plurality of openings, wherein the process medium reservoir is filled such that it overflows and thereby the process medium is driven through the openings onto the top surface;
by a transport element of a driving device of the processing device, which moves along the process path with the process good from accepting the process good to delivering the process good, moving the process good along the process path, the process good entering the process medium laterally and being moved through same or being passed by same while floating on the process medium; and
delivering the process good to an accepting device after having passed the process path.

23. The method in accordance with claim 22, wherein the movement of the process good, caused by the transport element, along the process path is a movement purely horizontal relative to the earth's gravitational field.

24. The method in accordance with claim 22, wherein the process good is semiconductor wafers or glass panels.

25. A device for handling a process good, comprising:
a delivery device comprising a first endless element which comprises a transport element for transporting the process good to a delivery region in which the endless element travels around an axis at a first radius;
an accepting device comprising a second endless element for accepting the process good in the delivery region and for transporting the process good from the delivery region, the second endless element traveling around the same axis at a second radius such that the second endless element moves faster than the first endless element,
wherein the ratio between the first and second radii is such that the second endless element moves the process good from a track of travel of the transport element around the axis at such a speed that the process good does not interfere in the movement of the transport element around the axis.
